(19) United States
(12) Patent Application Publication
(10) Pub. No.: US 2020/0368779 A1
(43) Pub. Date: Nov. 26, 2020

(54) VIBRATION DEVICE AND ACOUSTIC DEVICE

(71) Applicant: TDK Corporation, Tokyo (JP)

(72) Inventors: Akira SATOH, Tokyo (JP); Yoshikazu SHIMURA, Tokyo (JP); Kaoru KIJIMA, Tokyo (JP)

(73) Assignee: TDK Corporation, Tokyo (JP)

(21) Appl. No.: 16/871,094

(22) Filed: May 11, 2020

(30) Foreign Application Priority Data
May 20, 2019 (JP) 2019-094369

(51) Int. Cl. B06B 1/06; H01L 41/047; H01L 41/083; C09J 121/00

(52) U.S. Cl. CPC B06B 1/0603; H01L 41/0471; C09J 121/00; H01L 41/0475; H01L 41/083; H01L 41/0474

(57) ABSTRACT

A vibration device includes a piezoelectric element and an adhesive layer. The piezoelectric element includes a first principal surface and a second principal surface opposing each other. The adhesive layer is disposed on the first principal surface and is in contact with the first principal surface. A tensile strength of the adhesive layer is 10 N/cm or more and 48 N/cm or less.

### BACKGROUND OF THE INVENTION

### 1. Field of the Invention

A first aspect of the invention relates to a vibration device. A second aspect of the present invention relates to an acoustic device.

### 2. Description of Related Art

Known vibration devices include a piezoelectric element (for example, see Japanese Patent No. 5534040). In the vibration device disclosed in Japanese Patent No. 5534040, the piezoelectric element is bonded to a vibration member with an adhesive layer.

### SUMMARY OF THE INVENTION

In a configuration in which a piezoelectric element is bonded to a vibration member with an adhesive layer, the vibration member may prevent displacement of the piezoelectric element. That is, the vibration member may inhibit the displacement of the piezoelectric element. In a case where the vibration member inhibits the displacement of the piezoelectric element, the displacement of the vibration device decreases. In a case where an acoustic device includes the vibration device, sound pressure level of the acoustic device decreases.

A first aspect is to provide a vibration device that controls a decrease in displacement. A second aspect is to provide an acoustic device that controls a decrease in sound pressure level.

A vibration device according to the first aspect includes a piezoelectric element and an adhesive layer. The piezoelectric element includes a pair of principal surfaces opposing each other. The adhesive layer is disposed on one principal surface and is in contact with the one principal surface. A tensile strength of the adhesive layer is 10 N/cm or more and 48 N/cm or less.

As a result of research and study by the present inventors, the present inventors have discovered that the tensile strength of the adhesive layer is related to displacement of the vibration device. That is, in a case where the tensile strength of the adhesive layer is less than 10 N/cm, the displacement of the vibration device decreases. Even in a case where the tensile strength of the adhesive layer is more than 48 N/cm, the displacement of the vibration device decreases.

In the first aspect, the tensile strength of the adhesive layer is 10 N/cm or more and 48 N/cm or less. Therefore, the first aspect controls a decrease in the displacement.

An acoustic device according to the second aspect includes a piezoelectric element, an adhesive layer, and a vibration member. The piezoelectric element includes a pair of principal surfaces opposing each other. The adhesive layer is disposed on one principal surface and is in contact with the one principal surface. The vibration member is disposed such that the adhesive layer is located between the vibration member and the one principal surface and is in contact with the adhesive layer. A tensile strength of the adhesive layer is 10 N/cm or more and 48 N/cm or less.

As a result of research and study by the present inventors, the present inventors have discovered that the tensile strength of the adhesive layer is related to sound pressure level of the acoustic device. That is, in a case where the tensile strength of the adhesive layer is less than 10 N/cm, the sound pressure level of the acoustic device decreases. Even in a case where the tensile strength of the adhesive layer is more than 48 N/cm, the sound pressure level of the acoustic device decreases.

In the second aspect, the tensile strength of the adhesive layer is 10 N/cm or more and 48 N/cm or less. Therefore, the second aspect controls a decrease in the sound pressure level.

The adhesive layer may be made of a rubber-based adhesive.

The present invention will become more fully understood from the detailed description given hereinafter and the accompanying drawings which are given by way of illustration only, and thus are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a perspective view illustrating a vibration device according to an embodiment;

FIG. 2 is a view illustrating a cross-sectional configuration of the vibration device according to the embodiment;

FIG. 3 is an exploded perspective view of a piezoelectric element;

FIG. 4 is a perspective view illustrating an acoustic device according to an embodiment;

FIG. 5 is a view illustrating a cross-sectional configuration of the acoustic device according to the embodiment; and

FIG. 6 is a table illustrating displacement and sound pressure level of each sample.

### DETAILED DESCRIPTION OF EMBODIMENTS

Hereinafter, embodiments of the present invention will be described in detail with reference to the accompanying drawings. In the following description, the same elements or elements having the same functions are denoted with the same reference numerals and overlapped explanation is omitted.

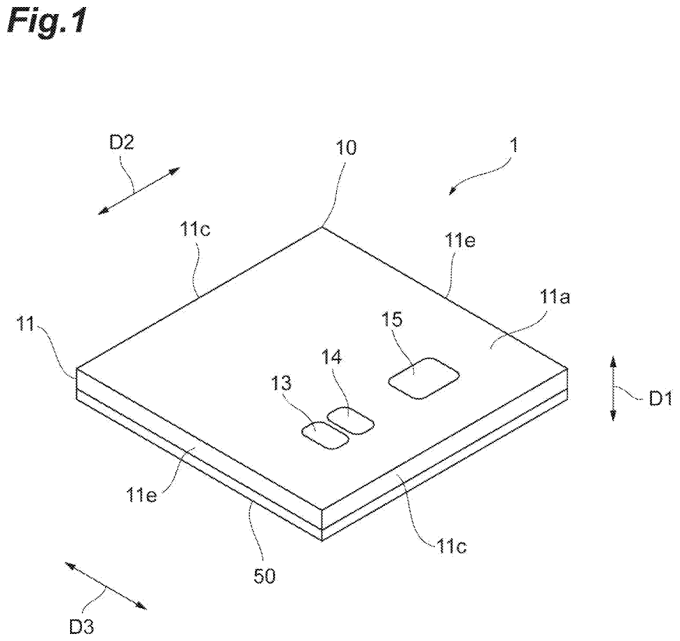

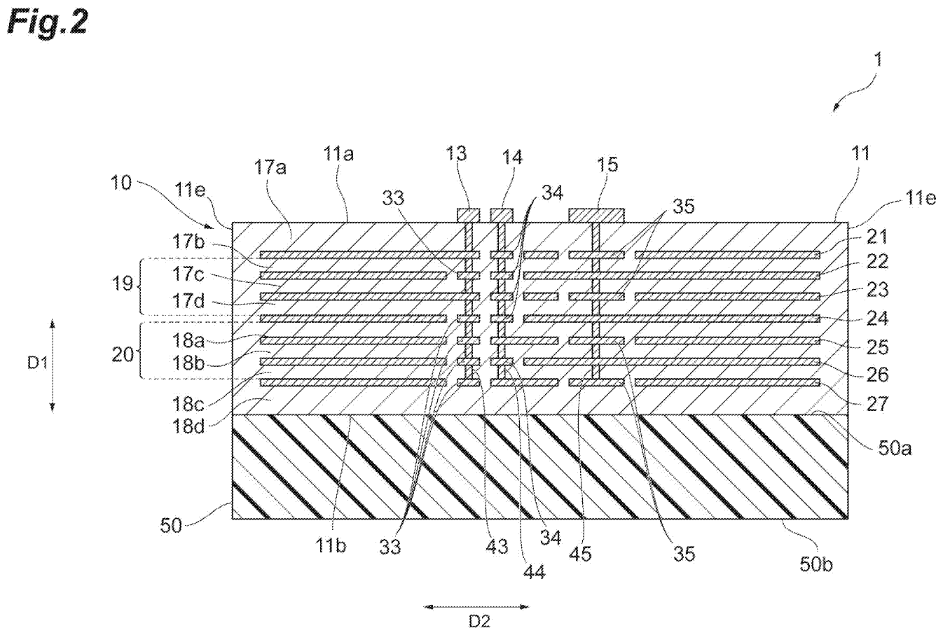

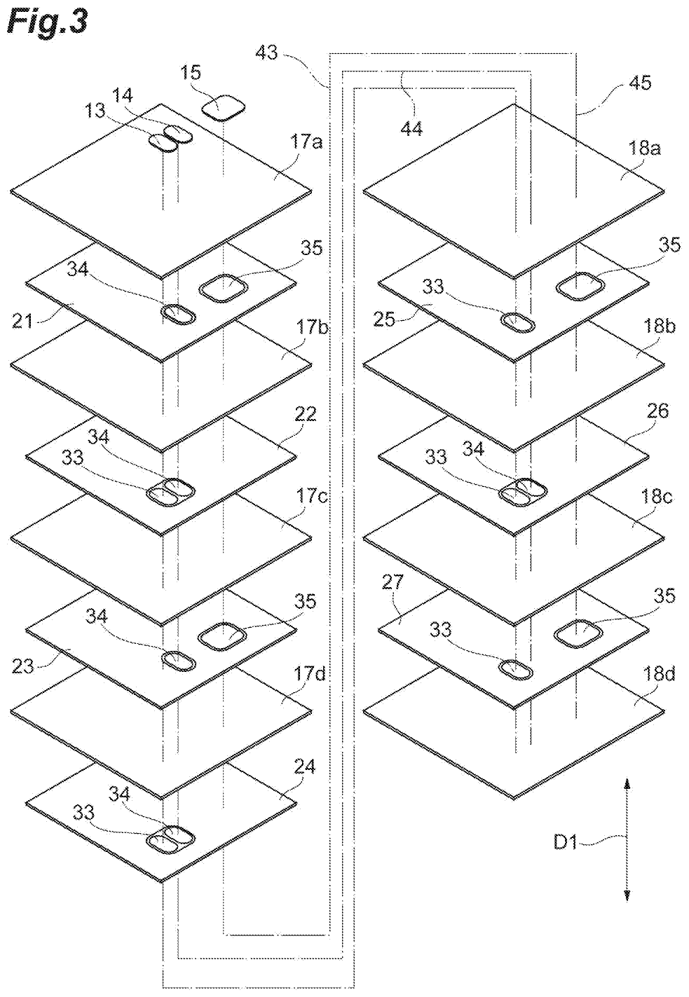

A configuration of the vibration device 1 according to an embodiment will be described with reference to FIGS. 1 to 3. FIG. 1 is a perspective view illustrating the vibration device according to the embodiment. FIG. 2 is a view illustrating a cross-sectional configuration of the vibration device according to the embodiment. FIG. 3 is an exploded perspective view of the piezoelectric element.

As illustrated in FIGS. 1 and 2, the vibration device 1 includes a piezoelectric element 10 and an adhesive layer 50. The piezoelectric element 10 is a bimorph-type piezoelectric element. The piezoelectric element 10 includes a piezoelectric element body 11 and a plurality of external electrodes 13, 14, and 15. In the embodiment, the piezoelectric element 10 includes three external electrodes 13, 14, and 15. The piezoelectric element 10 is a multilayer piezoelectric element.

The piezoelectric element body 11 has a rectangular parallelepiped shape. The piezoelectric element body 11 includes a pair of principal surfaces 11a and 11b opposing each other, a pair of side surfaces 11c opposing each other, and a pair of side surfaces 11e opposing each other. Therefore, the piezoelectric element 10 includes the pair of principal surfaces 11a and 11b. The rectangular parallelepiped shape in this specification includes a rectangular parallelepiped shape in which each corner and each ridge are chamfered and a rectangular parallelepiped shape in which each corner and each ridge are rounded. A direction in which the pair of principal surfaces 11a and 11b opposes each other is a first direction D1. The first direction D1 is also a direction perpendicular to the principal surfaces 11a and 11b. A direction in which the pair of side surfaces 11e opposes each other is a second direction D2. The second direction D2 is also a direction perpendicular to each side surface 11e. A direction in which the pair of side surfaces 11c opposes each other is a third direction D3. The third direction D3 is also a direction perpendicular to each side surface 11c. For example, in a case where the principal surface 11b constitutes the first principal surface, the principal surface 11a constitutes the second principal surface.

Each of the principal surfaces 11a and 11b includes four sides. Each of the principal surfaces 11a and 11b has a rectangular shape. In the embodiment, each of the principal surfaces 11a and 11b has a square shape. In this case, the piezoelectric element 10 (piezoelectric element body 11) has a square shape in plan view. Each of the principal surfaces 11a and 11b may have a rectangular shape including a pair of long sides and a pair of short sides. The rectangular shape in this specification includes, for example, a shape in which each corner is chamfered and a shape in which each corner is rounded. Each of the principal surfaces 11a and 11b may have a circular shape. In this case, the piezoelectric element 10 (piezoelectric element body 11) has a disc shape.

The pair of side surfaces 11c extends in the first direction D1 to couple the pair of principal surfaces 11a and 11b. The pair of side surfaces 11c also extends in the second direction D2. The pair of side surfaces 11e extends in the first direction D1 to couple the pair of principal surfaces 11a and 11b. The pair of side surfaces 11e also extends in the third direction D3. A length of the piezoelectric element body 11 in the second direction D2 is, for example, 30 mm. A length of the piezoelectric element body 11 in the third direction D3 is, for example, 30 mm. A length of the piezoelectric element body 11 in the first direction D1, that is, a thickness of the piezoelectric element body 11 is 0.49 mm, for example. Each of the principal surfaces 11a and 11b and each of the side surfaces 11c and 11e may be indirectly adjacent to each other. In this case, a ridge portion is located between each of the principal surfaces 11a and 11b and each of the side surfaces 11c and 11e.

In the piezoelectric element body 11, as illustrated in FIGS. 2 and 3, a plurality of piezoelectric layers 17a, 17b, 17c, 17d, 18a, 18b, 18c, and 18d are stacked in the first direction D1. In the embodiment, the piezoelectric element body 11 includes eight piezoelectric layers 17a, 17b, 17c, 17d, 18a, 18b, 18c, and 18d. The piezoelectric layer 17a includes the principal surface 11a. The piezoelectric layer 18d includes the principal surface 11b. The piezoelectric layers 17b, 17c, 17d, 18a, 18b, and 18c are located between the piezoelectric layer 17a and the piezoelectric layer 18d. Polarization directions of the piezoelectric layers 17b, 17d, 18a, and 18c are opposite to polarization directions of the piezoelectric layers 17c and 18b. In the embodiment, the piezoelectric layers 17a, 17b, 17c, 17d, 18a, 18b, 18c, and 18d have the same thickness. In this specification, the term “same” includes a range of manufacturing error.

Each of the piezoelectric layers 17a, 17b, 17c, 17d, 18a, 18b, 18c, and 18d is made of a piezoelectric material. In the embodiment, each of the piezoelectric layers 17a, 17b, 17c, 17d, 18a, 18b, 18c, and 18d contains a piezoelectric ceramic material. The piezoelectric ceramic material includes, for example, PZT [Pb(Zr,Ti)O₃], PT(PbTiO₃), PLZT [(Pb,La)(Zr,Ti)O₃], or barium titanate (BaTiO₃). Each of the piezoelectric layers 17a, 17b, 17c, 17d, 18a, 18b, 18c, and 18d includes, for example, a sintered body of a ceramic green sheet containing the above-mentioned piezoelectric ceramic material. In the actual piezoelectric element body 11, the piezoelectric layers 17a, 17b, 17c, 17d, 18a, 18b, 18c, and 18d are so integrated that the boundaries between the piezoelectric layers 17a, 17b, 17c, 17d, 18a, 18b, 18c, and 18d cannot be recognized.

Each of the external electrodes 13, 14, and 15 is disposed on the principal surface 11a. The external electrodes 13, 14, and 15 are disposed in the second direction D2 in the order of the external electrode 13, the external electrode 14, and the external electrode 15. The external electrode 13 and the external electrode 14 are adjacent to each other in the second direction D2. The external electrode 14 and the external electrode 15 are adjacent to each other in the second direction D2. In the second direction D2, the shortest distance between the external electrodes 14 and 15 is longer than the shortest distance between the external electrodes 13 and 14. Each of the external electrodes 13, 14, and 15 is separated from all edges (four sides) of the principal surface 11a when viewed from the first direction D1.

Each of the external electrodes 13, 14, and 15 has a rectangular shape when viewed from the first direction D1. Each of the external electrodes 13 and 14 has a rectangular shape including a pair of long sides and a pair of short sides when viewed from the first direction D1. In the embodiment, each of the external electrodes 13 and 14 has a rectangular shape in which each corner is rounded. The external electrode 15 has a square shape when viewed from the first direction D1. In the embodiment, the external electrode 15 has a square shape in which each corner is rounded. Each of the external electrodes 13, 14, and 15 contains an electrically conductive material. The electrically conductive material includes, for example, Ag, Pd, Pt, or Ag—Pd alloy. Each of the external electrodes 13, 14, and 15 is configured, for example, as a sintered body of an electrically conductive paste containing the above-mentioned electrically conductive material.

As illustrated in FIGS. 2 and 3, the piezoelectric element 10 includes a plurality of internal electrodes 21, 22, 23, 24, 25, 26, and 27 disposed in the piezoelectric element body 11. In the embodiment, the piezoelectric element 10 includes seven internal electrodes 21, 22, 23, 24, 25, 26, and 27. Each of the internal electrodes 21, 22, 23, 24, 25, 26, and 27 contains an electrically conductive material. The electrically conductive material includes, for example, Ag, Pd, Pt, or Ag—Pd alloy. Each of the internal electrodes 21, 22, 23, 24, 25, 26, and 27 is configured, for example, as a sintered body of an electrically conductive paste containing the above-mentioned electrically conductive material. In the embodiment, an outer shape of each of the internal electrodes 21, 22, 23, 24, 25, 26, and 27 is rectangular. Specifically, the outer shape of each of the internal electrodes 21, 22, 23, 24, 25, 26, and 27 includes a rectangular shape including a pair of long sides and a pair of short sides.

The internal electrodes 21, 22, 23, 24, 25, 26, and 27 are disposed at different positions (layers) in the first direction D1. The internal electrodes 21, 22, 23, 24, 25, 26, and 27 oppose each other with an interval therebetween in the first direction D1. The internal electrodes 21, 22, 23, 24, 25, 26, and 27 are not exposed on the surface of the piezoelectric element body 11. That is, the internal electrodes 21, 22, 23, 24, 25, 26, and 27 are not exposed on each of the side surfaces 11c and 11e. The internal electrodes 21, 22, 23, 24, 25, 26, and 27 are separated from all edges (four sides) of the principal surfaces 11a and 11b when viewed from the first direction D1.

The internal electrode 21 is located between the piezoelectric layer 17a and the piezoelectric layer 17b. The internal electrode 22 is located between the piezoelectric layer 17b and the piezoelectric layer 17c. The internal electrode 23 is located between the piezoelectric layer 17c and the piezoelectric layer 17d. The internal electrode 24 is located between the piezoelectric layer 17d and the piezoelectric layer 18a. The internal electrode 25 is located between the piezoelectric layer 18a and the piezoelectric layer 18b. The internal electrode 26 is located between the piezoelectric layer 18b and the piezoelectric layer 18c. The internal electrode 27 is located between the piezoelectric layer 18c and the piezoelectric layer 18d.

The external electrode 13 is electrically connected to the internal electrode 21, the internal electrode 23, and a plurality of connection conductors 33 through a plurality of via conductors 43. The plurality of connection conductors 33 are located in the same layer as the internal electrodes 22, 24, 25, 26, and 27, respectively. Each connection conductor 33 is located in an opening formed in each of the internal electrodes 22, 24, 25, 26, and 27. Each opening is formed at a position corresponding to the external electrode 13 when viewed from the first direction D1. Each connection conductor 33 is surrounded by each of the internal electrodes 22, 24, 25, 26, and 27 when viewed from the first direction D1. Each connection conductor 33 is separated from each of the internal electrodes 22, 24, 25, 26, and 27.

Each connection conductor 33 opposes the external electrode 13 in the first direction D1 and is disposed at a position overlapping the external electrode 13 when viewed from the first direction D1. Each connection conductor 33 opposes the internal electrodes 21 and 23 in the first direction D1 and is disposed at a position overlapping the internal electrodes 21 and 23 when viewed from the first direction D1. The plurality of via conductors 43 are located between the external electrode 13 and the internal electrode 21, between the internal electrode 21 and the connection conductor 33, between the internal electrode 23 and the connection conductor 33, and between the adjacent connection conductors 33, respectively. Each via conductor 43 is disposed at a position overlapping the external electrode 13 when viewed from the first direction D1. The plurality of via conductors 43 penetrate the corresponding piezoelectric layers 17a, 17b, 17c, 17d, 18a, 18b, and 18c, respectively, in the first direction D1.

The external electrode 14 is electrically connected to the internal electrode 25, the internal electrode 27, and the plurality of connection conductors 34 through a plurality of via conductors 44. The plurality of connection conductors 34 are located in the same layer as the internal electrodes 21, 22, 23, 24, and 26, respectively. Each connection conductor 34 is located in an opening formed in each of the internal electrodes 21, 22, 23, 24, and 26. Each opening is formed at a position corresponding to the external electrode 14 when viewed from the first direction D1. Each connection conductor 34 is surrounded by each of the internal electrodes 21, 22, 23, 24, and 26 when viewed from the first direction D1. Each connection conductor 34 is separated from each of the internal electrodes 21, 22, 23, 24, and 26. Each connection conductor 34 is separated from each connection conductor 33.

The connection conductor 33 and the connection conductor 34 located in the same layer as the internal electrode 22 are located adjacent to each other in the same opening. The connection conductor 33 and the connection conductor 34 located in the same layer as the internal electrode 24 are located adjacent to each other in the same opening. The connection conductor 33 and the connection conductor 34 located in the same layer as the internal electrode 26 are located adjacent to each other in the same opening.

Each connection conductor 34 opposes the external electrode 14 in the first direction D1 and is disposed at a position overlapping the external electrode 14 when viewed from the first direction D1. Each connection conductor 34 opposes the internal electrodes 25 and 27 in the first direction D1 and is disposed at a position overlapping the internal electrodes 25 and 27 when viewed from the first direction D1. The plurality of via conductors 44 are located between the external electrode 14 and the connection conductor 34, between the internal electrode 25 and the connection conductor 34, between the internal electrode 27 and the connection conductor 34, and between the adjacent connection conductors 34, respectively. The plurality of via conductors 44 are disposed at positions overlapping the external electrodes 14 when viewed from the first direction D1. The plurality of via conductors 44 penetrate the corresponding piezoelectric layers 17a, 17b, 17c, 17d, 18a, 18b, and 18c, respectively, in the first direction D1.

The external electrode 15 is electrically connected to the internal electrode 22, the internal electrode 24, the internal electrode 26, and the plurality of connection conductors 35 through a plurality of via conductors 45. The plurality of connection conductors 35 are located in the same layer as the internal electrodes 21, 23, 25, and 27, respectively. Each connection conductor 35 is located in an opening formed in each of the internal electrodes 21, 23, 25, and 27. Each opening is formed at a position corresponding to the external electrode 15 when viewed from the first direction D1. That is, an entire edge of each connection conductor 35 is surrounded by each of the internal electrodes 21, 23, 25, and 27 when viewed from the first direction D1. Each opening is formed at a position corresponding to the external electrode 15 when viewed from the first direction D1.

Each connection conductor 35 opposes the external electrode 15 in the first direction D1 and is disposed at a position overlapping the external electrode 15 when viewed from the first direction D1. Each connection conductor 35 opposes the internal electrodes 22, 24, and 26 in the first direction D1 and is disposed at a position overlapping the internal electrodes 22, 24, and 26 when viewed from the first direction D1. The plurality of via conductors 45 are located between the external electrode 15 and the connection conductor 35, between the internal electrode 22 and the connection conductor 35, between the internal electrode 24 and the connection conductor 35, and between the internal electrode 26 and the connection conductors 35, respectively. The plurality of via conductors 45 are disposed at positions overlapping the external electrode 15 when viewed from the first direction D1. The plurality of via conductors 45 penetrate the corresponding piezoelectric layers 17a, 17b, 17c, 17d, 18a, 18b, and 18c, respectively, in the first direction D1.

Each of the connection conductors 33, 34, and 35 has a rectangular shape when viewed from the first direction D1. Each of the connection conductors 33 and 34 has a rectangular shape including a pair of long sides and a pair of short sides when viewed from the first direction D1. In the embodiment, each of the connection conductors 33 and 34 has a rectangular shape in which each corner is rounded when viewed from the first direction D1. Each connection conductor 35 has a square shape when viewed from the first direction D1. In the embodiment, each connection conductor 35 has a square shape in which each corner is rounded when viewed from the first direction D1.

The connection conductors 33, 34, and 35 and the via conductors 43, 44, and 45 contain an electrically conductive material. The electrically conductive material includes, for example, Ag, Pd, Pt, or Ag—Pd alloy. The connection conductors 33, 34, and 35 and the via conductors 43, 44, and 45 are configured, for example, as a sintered body of an electrically conductive paste containing the above-mentioned electrically conductive material. The via conductors 43, 44, and 45 are formed by sintering the electrically conductive paste filled in the through-holes formed in the ceramic green sheet for forming the corresponding piezoelectric layers 17a, 17b, 17c, 17d, 18a, 18b, and 18c.

On the principal surface 11b of the piezoelectric element body 11, disposed are no conductor electrically connected to the internal electrodes 21 and 23, no conductor electrically connected to the internal electrodes 25 and 27, and no conductor electrically connected to the internal electrodes 22, 24, and 26. In the embodiment, when the principal surface 11b is viewed from the first direction D1, the entire principal surface 11b is exposed. The principal surfaces 11a and 11b are natural surfaces. The natural surface is a surface constituted by the surface of crystal grains grown by firing.

Also on each of the side surfaces 11c and 11e of the piezoelectric element body 11, disposed are no conductor electrically connected to the internal electrodes 21 and 23, no conductor electrically connected to the internal electrodes 25 and 27, and no conductor electrically connected to the internal electrodes 22, 24, and 26. In the embodiment, when each side surface 11c is viewed from the third direction D3, the entire side surface 11c is exposed. When each side surface 11e is viewed from the second direction D2, the entire side surface 11e is exposed. In the embodiment, each of the side surfaces 11c and 11e is also a natural surface.

In the plurality of piezoelectric layers 17b, 17c, and 17d, regions interposed between the internal electrodes 21 and 23 connected to the external electrode 13 and the internal electrodes 22 and 24 connected to the external electrode 15 constitute a first active region 19 that is piezoelectrically active. In the plurality of piezoelectric layers 18a, 18b, and 18c, regions interposed between the internal electrodes 25 and 27 connected to the external electrode 14 and the internal electrodes 24 and 26 connected to the external electrode 15 constitute a second active region 20 that is piezoelectrically active. The first active region 19 and the second active region 20 are disposed between the principal surface 11a and the principal surface 11b. The second active region 20 is disposed closer to the principal surface 11b than the first active region 19. The first active region 19 and the second active region 20 are configured with at least one piezoelectric layer.

In the embodiment, the first active region 19 and the second active region 20 are located to surround the plurality of external electrodes 13, 14, and 15 when viewed from the first direction D1. The first active region 19 and the second active region 20 includes a region located between the external electrode 14 and the external electrode 15 when viewed from the first direction D1 and a region outside the region where the external electrodes 13, 14, and 15 when viewed from the first direction D1 are located.

A region of the piezoelectric element body 11 that overlaps with the external electrodes 13 and 14 (connection conductors 33 and 34) when viewed from the first direction D1 is piezoelectrically inactive. A region of the piezoelectric element body 11 that overlaps with the external electrode 15 (connection conductor 35) when viewed from the first direction D1 is also piezoelectrically inactive. Hereinafter, the piezoelectrically inactive region will be referred to as an “inactive region”. In the piezoelectric element 10, the inactive region is surrounded by the first active region 19 and the second active region 20 when viewed from the first direction D1. When viewed from the first direction D1, the inactive region is located to be deviated from a center of the piezoelectric element body 11 (principal surfaces 11a and 11b).

The adhesive layer 50 is disposed on the principal surface 11b. The adhesive layer 50 includes a pair of principal surfaces 50a and 50b opposing each other. The principal surface 50a is in contact with the principal surface 11b. That is, the adhesive layer 50 is in direct contact with the principal surface 11b. The adhesive layer 50 adheres to the principal surface 11b due to adhesiveness of the adhesive layer 50. The adhesive layer 50 does not include electrically conductive fillers and has electric insulation. The adhesive layer 50 is made of, for example, a rubber-based adhesive. The adhesive layer 50 does not include a base material having no adhesiveness. A tensile strength of the adhesive layer 50 is 10 N/cm or more and 48 N/cm or less. A thickness of the adhesive layer 50 is, for example, 0.1 to 0.8 mm.

The principal surfaces 50a and 50b have, for example, a rectangular shape. The principal surfaces 50a and 50b may have, for example, a circular shape or a frame shape. That is, the adhesive layer 50 may have a circular shape or a frame shape in plan view. The principal surfaces 50a and 50b may have the same shape and the same area as the principal surface 11b. In this case, the entire principal surface 11b may be covered with the adhesive layer 50 when viewed from the first direction D1. The principal surfaces 50a and 50b may have different shapes and different areas from the principal surface 11b. In this case, a part of the principal surface 11b may be exposed from the adhesive layer 50 when viewed from the first direction D1. In the embodiment, the principal surfaces 50a and 50b have the same shape and the same area as the principal surface 11b, and the entire principal surface 11b is covered with the adhesive layer 50 when viewed from the first direction D1. In a case where the adhesive layer 50 has a frame shape in plan view, the adhesive layer 50 includes, for example, a portion along each side of the principal surface 11b.

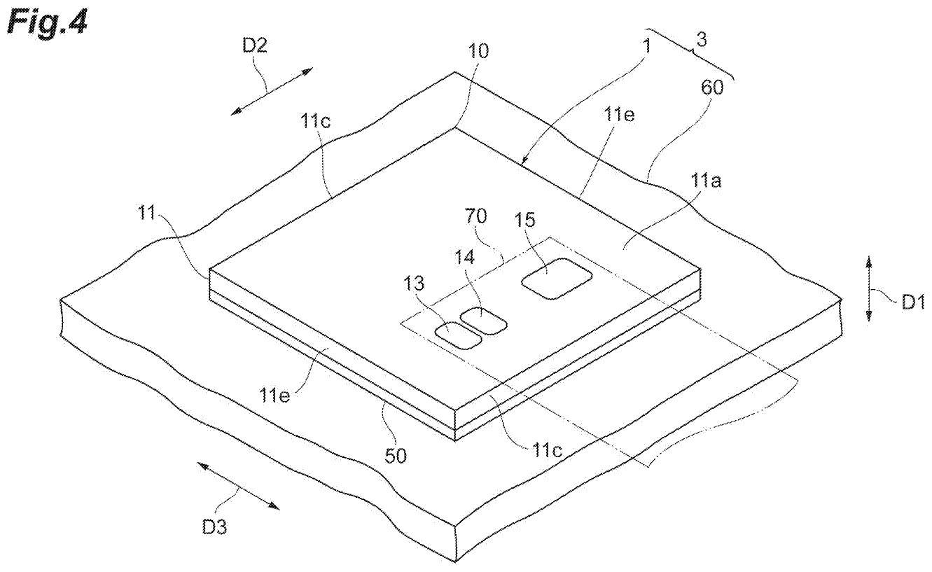

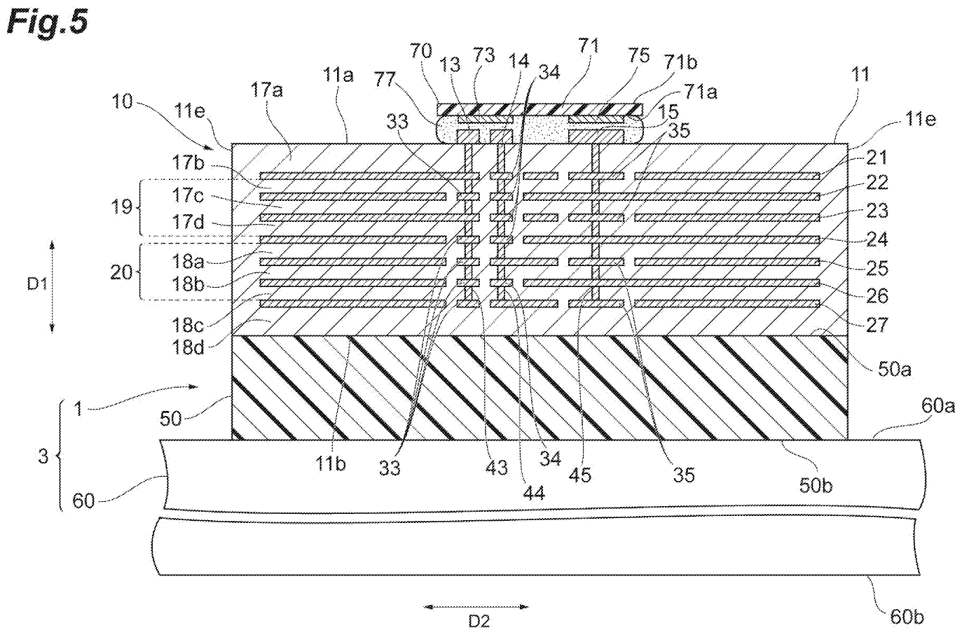

A configuration of an acoustic device 3 according to the embodiment will be described with reference to FIGS. 4 and 5. FIG. 4 is a perspective view illustrating the acoustic device according to the embodiment. FIG. 5 is a view illustrating a cross-sectional configuration of the acoustic device according to the embodiment.

The acoustic device 3 includes the vibration device 1 (the piezoelectric element 10 and the adhesive layer 50) and a vibration member 60.

The vibration member 60 includes principal surfaces 60a and 60b opposing each other. In the embodiment, the vibration member 60 is a vibration plate. The vibration device 1 is disposed on the principal surface 60a. The principal surface 50b is in contact with the principal surface 60a. That is, the adhesive layer 50 is in direct contact with the principal surface 60a. The adhesive layer 50 adheres to the principal surface 60a due to the adhesiveness of the adhesive layer 50. Due to the adhesiveness of the adhesive layer 50, the piezoelectric element 10 is attached to the vibration member 60. The adhesive layer 50 can be peeled off from the principal surface 11b and the principal surface 60a. That is, the adhesive layer 50 can be peeled off from the piezoelectric element 10 (piezoelectric element body 11) and the vibration member 60. The adhesive layer 50 is located between the piezoelectric element 10 and the vibration member 60. In a case where the adhesive layer 50 has a frame shape in plan view, an acoustic space is defined by the piezoelectric element 10, the adhesive layer 50, and the vibration member 60. The acoustic space may communicate with an external space through a communication hole formed in at least one of the adhesive layer 50 and the vibration member 60.

The vibration member 60 may contain, for example, a synthetic resin. In this case, the vibration member 60 contains, for example, an acrylic resin, a polyimide resin, a polycarbonate resin, an ABS resin (acrylonitrile-butadiene-styrene copolymer resin), a vinyl chloride resin, or a PET resin (polyethylene terephthalate resin). The vibration member 60 may contain, for example, a metal. In this case, the vibration member 60 contains, for example, Ni or an alloy thereof, Fe or an alloy thereof, Al or an alloy thereof, Mg or an alloy thereof, Cu or an alloy thereof, or stainless steel. The vibration member 60 may contain, for example, a glass. The vibration member 60 (principal surfaces 60a and 60b) has, for example, a rectangular shape when viewed from the first direction D1. A thickness of the vibration member 60 is, for example, 0.01 to 50 mm.

As illustrated in FIGS. 4 and 5, a wiring member 70 is connected to the piezoelectric element 10. The wiring member 70 includes a base 71, a plurality of conductors 73 and 75, and a cover (not illustrated). In the embodiment, the wiring member 70 includes two conductors 73 and 75. The wiring member 70 is, for example, a flexible printed circuit board (FPC) or a flexible flat cable (FFC). The wiring member 70 may include a reinforcing member (not illustrated).

The base 71 has a strip shape. The base 71 includes a pair of principal surfaces 71a and 71b opposing each other. The base 71 has electric insulation. The base 71 is, for example, a layer made of a resin. The base 71 is made of, for example, a polyimide resin. A thickness of the base 71 is, for example, 25 μm.

The conductors 73 and 75 are disposed on the principal surface 71a. Each of the conductors 73 and 75 is bonded to the principal surface 71a with an adhesive layer (not illustrated). Each of the conductors 73 and 75 is made of, for example, Cu. Each of the conductors 73 and 75 may have a configuration in which an Ni-plated layer and an Au-plated layer are disposed in this order on a Cu layer. The conductor 73 and the conductor 75 are disposed to be separated from each other. A thickness of each of the conductor 73 and 75 is, for example, 20 μm.

The cover is disposed on the principal surface 71a. The cover covers a part of the conductor 73, a part of the conductor 75, and a part of the principal surface 71a. The cover is bonded to the parts of the conductor 73, conductor 75, and principal surface 71a that are covered with the cover, with an adhesive layer (not illustrated). The cover is a layer made of, for example, a resin. The cover is made of, for example, a polyimide resin. A thickness of the cover is, for example, 25 μm. The cover may be bonded to the principal surface 11a with a bonding member.

The wiring member 70 is bonded to the piezoelectric element 10 with a bonding member 77. Specifically, one end of the wiring member 70 is bonded to the external electrodes 13, 14, and 15 and the principal surface 11a with the bonding member 77. The bonding member 77 is a resin layer containing a plurality of electrically conductive particles (not illustrated) and has electric conductiveness. The electrically conductive particles are, for example, metal particles or gold-plated particles. The bonding member 77 contains, for example, a thermosetting elastomer. The bonding member 77 is formed by curing, for example, an anisotropic electrically conductive paste or an anisotropic electrically conductive film.

The bonding member 77 is located between the conductor 73 and the external electrodes 13 and 14. The conductor 73 and the external electrodes 13 and 14 are electrically connected through the electrically conductive particles contained in the bonding member 77. The bonding member 77 is located between the conductor 75 and the external electrode 15. The conductor 75 and the external electrode 15 are electrically connected through the electrically conductive particles contained in the bonding member 77.

The same voltage is applied to the external electrode 13 and the external electrode 14 through the conductor 73. Therefore, in a case where an electric field is generated in the piezoelectric layers 17b, 17c, and 17d in a direction along the polarization direction of the piezoelectric layers 17b, 17c, and 17d, an electric field is generated in the piezoelectric layers 18a, 18b, and 18c in a direction opposite to the polarization direction of the piezoelectric layers 18a, 18b, and 18c. In addition, in a case where an electric field is generated in the piezoelectric layers 17b, 17c, and 17d in a direction opposite to the polarization direction of the piezoelectric layers 17b, 17c, and 17d, an electric field is generated in the piezoelectric layers 18a, 18b, and 18c in a direction along the polarization direction of the piezoelectric layers 18a, 18b, and 18c. Consequently, the first active region 19 and the second active region 20 expand and contract in opposite directions, and the piezoelectric element 10 vibrates by bending.

A relationship between the tensile strength of the adhesive layer 50 and displacement of the vibration device 1 and a relationship between the tensile strength of the adhesive layer 50 and sound pressure level of the acoustic device 3 will be described in detail.

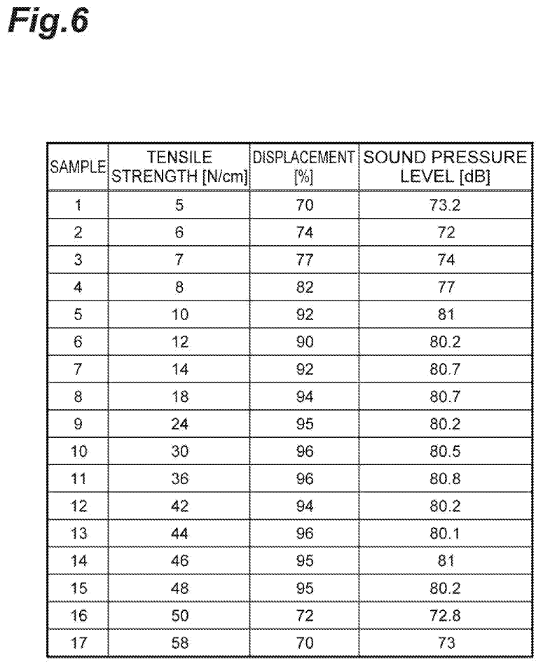

The present inventors carried out the following test in order to clarify the above-mentioned relationships. That is, the present inventors prepared Samples 1 to 17 having different tensile strengths of the adhesive layer 50 and confirmed the displacement and the sound pressure level in each of Samples 1 to 17. The result of the test is illustrated in FIG. 6. FIG. 6 is a table illustrating the displacement and the sound pressure level of each of Samples.

Each of Samples 1 to 17 is an acoustic device having the same configuration except that the tensile strength of the adhesive layer 50 is different. That is, each of Samples 1 to 17 includes the vibration device 1 and the vibration member 60 that are described above. The vibration member 60 is a vibration plate made of a polycarbonate resin. The size of the vibration plate is 220 mm×220 mm, and the thickness of the vibration plate is 1 mm. In the test, the tensile strength of the adhesive layer 50 is allowed to be different by allowing an adhesive strength of the adhesive constituting the adhesive layer 50 to be different. The tensile strength of the adhesive layer 50 is obtained by a tensile test (ISO 29862).

In Sample 1, the tensile strength of the adhesive layer 50 is 5 N/cm. In Sample 2, the tensile strength of the adhesive layer 50 is 6 N/cm. In Sample 3, the tensile strength of the adhesive layer 50 is 7 N/cm. In Sample 4, the tensile strength of the adhesive layer 50 is 8 N/cm. In Sample 5, the tensile strength of the adhesive layer 50 is 10 N/cm. In Sample 6, the tensile strength of the adhesive layer 50 is 12 N/cm. In Sample 7, the tensile strength of the adhesive layer 50 is 14 N/cm. In Sample 8, the tensile strength of the adhesive layer 50 is 18 N/cm. In Sample 9, the tensile strength of the adhesive layer 50 is 24 N/cm.

In Sample 10, the tensile strength of the adhesive layer 50 is 30 N/cm. In Sample 11, the tensile strength of the adhesive layer 50 is 36 N/cm. In Sample 12, the tensile strength of the adhesive layer 50 is 42 N/cm. In Sample 13, the tensile strength of the adhesive layer 50 is 44 N/cm. In Sample 14, the tensile strength of the adhesive layer 50 is 46 N/cm. In Sample 15, the tensile strength of the adhesive layer 50 is 48 N/cm. In Sample 16, the tensile strength of the adhesive layer 50 is 50 N/cm. In Sample 17, the tensile strength of the adhesive layer 50 is 58 N/cm.

The displacement of each of Samples 1 to 17 was confirmed as follows.

A predetermined alternating voltage was applied to each of Samples 1 to 17, and the displacement of each of Samples 1 to 17 was directly measured. A laser displacement meter was used to measure the displacement of each of Samples 1 to 17. The value (measured value) obtained by the measurement was divided by the following calculated value and expressed as a percentage. The calculated value was calculated by simulation. In this simulation, the displacement of the acoustic device 3 of a case where the displacement of the piezoelectric element 10 is transmitted to the vibration member 60 without being disturbed is calculated. The calculated displacement is the above-mentioned calculated value. The alternating voltage applied is a sine wave. In this test, the frequency of the alternating voltage is 250 Hz, and the amplitude of the voltage is ±6 V.

In each of Samples 5 to 15, the measured value was 90% or more of the calculated value, and thus, the effect of controlling a decrease in the displacement was confirmed. In each of Samples 1 to 3, 6, and 17, the measured value is less than 80% of the calculated value, and thus, the effect of controlling a decrease in the displacement tends not to be confirmed.

The sound pressure level of each of Samples 1 to 17 was confirmed as follows.

The above-mentioned predetermined alternating voltage was applied to each of Samples 1 to 17, and a sound pressure signal emitted from the acoustic device 3 was detected by a microphone. The sound pressure level of the detected sound pressure signal was obtained. The distance between the microphone and the vibration member 60 is 1 m.

In each of Samples 5 to 15, the sound pressure level was more than 80 dB, and thus, the effect of controlling a decrease in the sound pressure level was confirmed. In each of Samples 1 to 3, 6, and 17, the sound pressure level is less than 75 dB, and thus, the effect of controlling a decrease in the displacement tends not to be confirmed.

As described above, in the vibration device 1, the tensile strength of the adhesive layer 50 is 10 N/cm or more and 48 N/cm or less. Therefore, the vibration device 1 controls a decrease in the displacement.

In the acoustic device 3, the tensile strength of the adhesive layer 50 is 10 N/cm or more and 48 N/cm or less. Therefore, the acoustic device 3 controls a decrease in the sound pressure level.

In the piezoelectric element 10, as described above, the inactive region is surrounded by the first active region 19 and the second active region 20 when viewed from the first direction D1 and is located to be deviated from the center of the piezoelectric element body 11 (principal surfaces 11a and 11b). In this case, a position where the displacement is maximized may be deviated from the center of the piezoelectric element body 11 (principal surfaces 11a and 11b). Even in the vibration device 1 including such the piezoelectric element 10, the vibration device 1 controls a decrease in the displacement because the tensile strength of the adhesive layer 50 is 10 N/cm or more and 48 N/cm or less.

Although the embodiments and modifications of the present invention have been described above, the present invention is not necessarily limited to the embodiments and modifications, and the embodiment can be variously changed without departing from the scope of the invention.

The number of internal electrodes, the number of piezoelectric layers, and the number of external electrodes included in the piezoelectric element 10 are not limited to the numbers disclosed in the above-described embodiments.

The vibration member 60 may be a housing of an electronic device or the like. The vibration member 60 may be a member different from the housing of the electronic device or the like. The vibration member 60 may be, for example, a display panel or a film material. The display panel includes, for example, a flexible organic EL display panel.

What is claimed is:

1. A vibration device comprising:
a piezoelectric element including first and second principal surfaces opposing each other; and
an adhesive layer being disposed on the first principal surface and being in contact with the first principal surface,
wherein a tensile strength of the adhesive layer is 10 N/cm or more and 48 N/cm or less.

2. The vibration device according to claim 1, wherein the adhesive layer is made of a rubber-based adhesive.

3. An acoustic device comprising:
a piezoelectric element including first and second principal surfaces opposing each other;
an adhesive layer being disposed on the first principal surface and being in contact with the first principal surface; and
a vibration member being disposed such that the adhesive layer is located between the vibration member and the first principal surface and being in contact with the adhesive layer,
wherein a tensile strength of the adhesive layer is 10 N/cm or more and 48 N/cm or less.

4. The acoustic device according to claim 3, wherein the adhesive layer is made of a rubber-based adhesive.
